(19) United States
(12) Patent Application Publication
(10) Pub. No.: US 2022/0141400 A1
(43) Pub. Date: May 5, 2022

(54) COLOR AND INFRARED IMAGE SENSOR

(71) Applicant: ISORG, Limoges CEDEX3 (FR)

(72) Inventors: Camille DUPOIRON, GRENOBLE (FR); Benjamin BOUTHINON, GRENOBLE (FR)

(21) Appl. No.: 17/435,347

(22) PCT Filed: Feb. 21, 2020
(86) PCT No.: PCT/FR2020/050338

§ 371 Date: Aug. 31, 2021

(30) Foreign Application Priority Data
Mar. 1, 2019 (FR) 19/02158

(51) Int. Cl. H04N 5/33; H01L 27/30

(52) U.S. Cl. CPC H04N 5/332; H01L 27/307

(57) ABSTRACT

A color and infrared image sensor includes a silicon substrate, MOS transistors formed in the substrate and on the substrate, first photodiodes at least partly formed in the substrate, separate photosensitive blocks covering the substrate, and color filters covering the substrate, the image sensor further including first and second electrodes on either side of each photosensitive block and delimiting a second photodiode in each photosensitive block. The first photodiodes are configured to absorb the electromagnetic waves of the visible spectrum and each photosensitive block is configured to absorb the electromagnetic waves of the visible spectrum of a first portion of the infrared spectrum.

### CROSS REFERENCE TO RELATED APPLICATIONS

The present patent application claims the priority benefit of French patent application FR19/02158 which is herein incorporated by reference.

### FIELD

The present disclosure relates to an image sensor or electronic imager.

### BACKGROUND

Image sensors are used in many fields, in particular in electronic devices, due to their miniaturization. Image sensors are present, be it in man-machine interface applications or in image capture applications.

For certain applications, it is desirable to have an image sensor enabling to simultaneously acquire a color image and an infrared image. Such an image sensor is called color and infrared image sensor in the following description. An example of application of a color and infrared image sensor concerns the acquisition of an infrared image of an object having a structured infrared pattern projected thereon. The fields of use of such image sensors particularly are motors vehicles, drones, smart phones, robotics, and augmented reality systems.

The phase during which a pixel collects charges under the action of an incident radiation is called integration phase of the pixel. The integration phase is generally followed by a readout phase during which the quantity of charges collected by the pixels is measured.

A plurality of constraints are to be taken into account for the design of a color and infrared image sensor. First, the resolution of the color images should not be smaller than that obtained with a conventional color image sensor.

Second, for certain applications, it may be desirable for the image sensor to be of global shutter type, that is, implementing an image acquisition method where the beginnings and ends of pixel integration phases are simultaneous. This may in particular apply for the acquisition of an infrared image of an object having a structured infrared pattern projected thereon.

Third, it is desirable for the size of the image sensor pixels to be as small as possible. Fourth, it is desirable for the filling factor of each pixel, which corresponds to the ratio of the surface area, in top view, of the area of the pixel actively taking part in the capture of the incident radiation, to the total surface area, in top view, of the pixel, to be as large as possible.

It may be difficult to design a color and infrared image sensor which fulfils all the previously-described constraints.

### SUMMARY

An embodiment overcomes all or part of the disadvantages of the previously-described color and infrared image sensors.

According to an embodiment, the resolution of the color images acquired by the color and infrared image sensor is greater than 2,560 ppi, preferably greater than 8,530 ppi.

According to an embodiment, the method of acquisition of an infrared image is of global shutter type.

According to an embodiment, the size of the color and infrared image sensor pixel is smaller than 10 μm, preferably smaller than 3 μm.

According to an embodiment, the filling factor of each pixel of the color and infrared image sensor is greater than 50%, preferably greater than 80%.

An embodiment provides a color and infrared image sensor comprising a silicon substrate, MOS transistors formed in the substrate and on the substrate, first photodiodes at least partly formed in the substrate, separate photosensitive blocks covering the substrate, and color filters covering the substrate, the image sensor further comprising first and second electrodes on either side of each photosensitive block and delimiting a second photodiode in each photosensitive block, the first photodiodes being configured to absorb the electromagnetic waves of the visible spectrum and each photosensitive block being configured to absorb the electromagnetic waves of the visible spectrum and of a first portion of the infrared spectrum.

According to an embodiment, the image sensor further comprises an infrared filter, the color filters being interposed between the substrate and the infrared filter, the infrared filter being configured to give way to the electromagnetic waves of the visible spectrum, to give way to the electromagnetic waves of said first portion of the infrared spectrum, and to block the electromagnetic waves of at least a second portion of the infrared spectrum between the visible spectrum and the first portion of the infrared spectrum.

According to an embodiment, the photosensitive blocks and the color filters are at the same distance from the substrate.

According to an embodiment, the photosensitive blocks are closer to the substrate than the color filters.

According to an embodiment, each photosensitive block is covered with a visible light filter made of organic materials.

According to an embodiment, the image sensor further comprises an array of lenses interposed between the substrate and the infrared filter.

According to an embodiment, the image sensor further comprises, for each pixel of the color image to be acquired, at least first, second, and third sub-pixels each comprising one of the first photodiodes and one of the color filters, the color filters of the first, second, and third sub-pixels giving way to electromagnetic waves in different frequency ranges of the visible spectrum, and a fourth sub-pixel comprising one of the second photodiodes.

According to an embodiment, the image sensor further comprises, for each first, second, and third sub-pixel, a first readout circuit coupled to the first photodiode and, for the fourth sub-pixel, a second readout circuit coupled to the second photodiode.

According to an embodiment, for each pixel of the color image to be acquired, the first readout circuits are configured to transfer first electric charges generated in the first photodiodes to a first electrically-conductive track and the second readout circuit is configured to transfer second charges generated in the second photodiode to the first electrically-conductive track or a second electrically-conductive track.

According to an embodiment, the first photodiodes are arranged in rows and in columns and the first readout circuits are configured to control the generation of the first charges during first time intervals simultaneous for all the first photodiodes of the image sensor or shifted in time from one row of first photodiodes to the other or, for each pixel of the color image to be acquired, shifted in time for the first, second, and third sub-pixels.

According to an embodiment, the second photodiodes are arranged in rows and in columns and the second readout circuits are configured to control the generation of the second charges during second time intervals simultaneous for all the second photodiodes of the image sensor.

According to an embodiment, the photosensitive layer is made of organic materials.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified exploded perspective view of an embodiment of a color and infrared image sensor;

FIG. 2 is a partial simplified cross-section view of the image sensor of FIG. 1;

FIG. 3 is a partial simplified exploded perspective view of another embodiment of a color and infrared image sensor;

FIG. 4 is a partial simplified cross-section view of the image sensor of FIG. 3;

FIG. 5 is an electric diagram of an embodiment of a readout circuit of a sub-pixel of the image sensor of FIG. 1; and

FIG. 6 is a timing diagram of signals of an embodiment of an operating method of the image sensor having the readout circuit of FIG. 5.

### DESCRIPTION OF THE EMBODIMENTS

Like features have been designated by like references in the various figures. In particular, the structural and/or functional features that are common among the various embodiments may have the same references and may dispose identical structural, dimensional and material properties. For clarity, only those steps and elements which are useful to the understanding of the described embodiments have been shown and are detailed. In particular, what use is made of the image sensors described hereafter has not been detailed.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures, or to an image sensor as orientated during normal use. Unless specified otherwise, the expressions “around”, “approximately”, “substantially” and “in the order of” signify within 10%, and preferably within 5%.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Further, a signal which alternates between a first constant state, for example, a low state, noted “0”, and a second constant state, for example, a high state, noted “1”, is called “binary signal”. The high and low states of different binary signals of a same electronic circuit may be different. In particular, the binary signals may correspond to voltages or to currents which may not be perfectly constant in the high or low state. Further, it is here considered that the terms “insulating” and “conductive” respectively mean “electrically insulating” and “electrically conductive”.

The transmittance of a layer corresponds to the ratio of the intensity of the radiation coming out of the layer to the intensity of the radiation entering the layer. In the following description, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%. In the following description, the refraction index of a material corresponds to the refraction index of the material for the wavelength range of the radiation captured by the image sensor. Unless specified otherwise, the refraction index is considered as substantially constant over the wavelength range of the useful radiation, for example, equal to the average of the refraction index over the wavelength range of the radiation captured by the image sensor.

In the following description, “visible light” designates an electromagnetic radiation having a wavelength in the range from 400 nm to 700 nm and “infrared radiation” designates an electromagnetic radiation having a wavelength in the range from 700 nm to 1 mm. In infrared radiation, one can particularly distinguish near infrared radiation having a wavelength in the range from 700 nm to 1.4 μm.

A pixel of an image corresponds to the unit element of the image captured by an image sensor. When the optoelectronic device is a color image sensor, it generally comprises, for each pixel of the color image to be acquired, at least three components which each acquire a light radiation substantially in a single color, that is, in a wavelength range below 100 nm (for example, red, green, and blue). Each component may particularly comprise at least one photodetector.

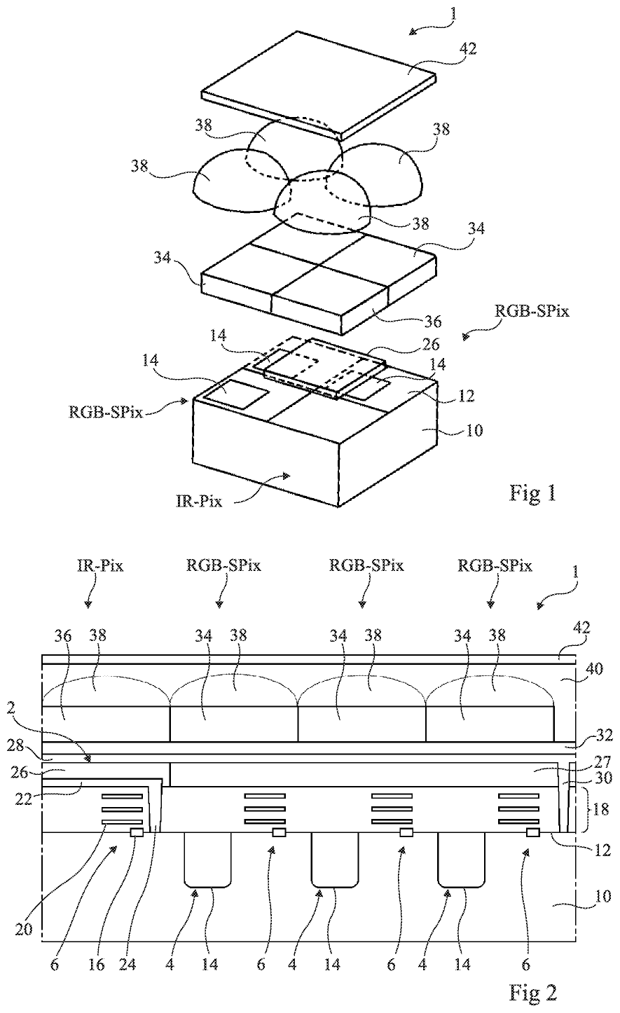

FIG. 1 is a partial simplified exploded perspective view and FIG. 2 is a partial simplified cross-section view of an embodiment of a color and infrared image sensor 1. Image sensor 1 comprises an array of first photon sensors 2, also called photodetectors, capable of capturing an infrared image, and an array of second photodetectors 4, capable of capturing a color image. The arrays of photodetectors 2 and 4 are associated with an array of readout circuits 6 measuring the signals captured by photodetectors 2 and 4. Readout circuit means an assembly of transistors for reading out, addressing, and controlling the pixel or sub-pixel defined by the corresponding photodetectors 2 and 4.

For each pixel of the color image and of the infrared image to be acquired, call color sub-pixel RGB-SPix of image sensor 1 the portion of image sensor 1 comprising color photodetector 4 enabling to acquire the light radiation in a limited portion of the visible radiation of the image and call infrared pixel IR-Pix the portion of image sensor 1 comprising infrared photodetector 2 enabling to acquire the infrared radiation of the pixel of the infrared image.

FIGS. 1 and 2 show three color sub-pixels RGB-SPix and one infrared pixel IR-Pix associated with a pixel of the color and infrared images. In the present embodiment, the acquired color image and infrared image have the same resolution so that infrared pixel IR-Pix may also be considered as another sub-pixel of the pixel of the acquired color image. For clarity, only certain elements of the image sensor present in FIG. 2 are shown in FIG. 1. Image sensor 1 comprises from bottom to top in FIG. 2:
a semiconductor substrate 10 comprising an upper surface 12, preferably planar;
for each color sub-pixel RGB-SPix, at least one doped semiconductor region 14 formed in substrate 10 and forming part of color photodiode 4;
electronic components 16 of readout circuits 6 located in substrate 10 and/or on surface 12, a single component 16 being shown in FIG. 2;
a stack 18 of insulating layers covering surface 12, conductive tracks 20 being located on stack 18 and between the insulating layers of stack 18;
for each infrared pixel IR-Pix, an electrode 22 resting on stack 18 and coupled to substrate 10, to one of components 16, or to one of conductive tracks 20 by a conductive via 24;
for each infrared pixel IR-Pix, an active layer 26 covering electrode 22 and possibly covering stack 18 around electrode 22, which active layer 26 only extends, in top view, over the surface of infrared pixel IR-Pix and does not extend over the surfaces of color sub-pixels RGB-Pix;
for all the color sub-pixels RGB-SPix, an insulating layer 27 covering stack 18;
for each infrared pixel IR-Pix, an electrode 28 covering active layer 26 and possibly insulating layer 27, coupled to substrate 10, to one of components 16, or to one of conductive tracks 20 by a conductive via 30;
an insulating layer 32 covering electrodes 28;
for each color sub-pixel RGB-SPix, a color filter 34 covering insulating layer 32, and, for infrared pixel IR-Pix, a block 36 transparent to infrared radiations covering insulating layer 32;
for each color sub-pixel RGB-SPix and for infrared pixel IR-Pix, a microlens 38 covering color filer 34 or transparent block 36;
an insulating layer 40 covering microlenses 38; and
a filter 42 covering insulating layer 40.

Color sub-pixels RGB-SPix and infrared pixels IR-Pix may be distributed in rows and in columns. In the present embodiment, each color sub-pixel RGB-Pix and each infrared pixel IR-Pix has, in a direction perpendicular to surface 12, a square or rectangular base with a side length varying from 0.1 μm to 100 μm, for example, equal to approximately 3 μm. However, each sub-pixel SPix may have a base with a different shape, for example, hexagonal.

In the present embodiment, active layer 26 is present only at the level of the infrared pixels IR-Pix of image sensor 1. The active area of each infrared photodetector 2 corresponds to the area where most of the useful incident infrared radiation is absorbed and converted into an electric signal by infrared photodetector 2 and substantially corresponds to the portion of active layer 26 located between lower electrode 22 and upper electrode 28.

According to an embodiment, active layer 26 is capable of capturing an electromagnetic radiation in a wavelength range from 400 nm to 1,100 nm. Infrared photodetectors 2 may be made of organic materials. The photodetectors may correspond to organic photodiodes (OPD) or to organic photoresistors. In the following description, it is considered that the photodetectors 2 correspond to photodiodes.

Filter 42 is capable of giving way to visible light, of giving way to a portion of the infrared radiation over the infrared wavelength range of interest for the acquisition of the infrared image, and of blocking the rest of the incident radiation, and particularly the rest of the infrared radiation outside of the infrared wavelength range of interest. According to an embodiment, the infrared wavelength range of interest may correspond to a 50-nm range centered on the expected wavelength of the infrared radiation, for example, centered on the 940-nm wavelength or centered on the 850-nm wavelength. Filter 42 may be an interference filter and/or may comprise absorbing and/or reflective layers.

Color filters 34 may correspond to colored resin blocks. Each color filter 34 is capable of giving way to a wavelength range of visible light. For each pixel of the color image to be acquired, the image sensor may comprise a color sub-pixel RGB-SPix having its color filter 34 only capable of giving way to blue light, for example, in the wavelength range from 430 nm to 490 nm, a color sub-pixel RGB-SPix having its color filter 34 only capable of giving way to green light, for example, in the wavelength range from 510 nm to 570 nm, and a color sub-pixel RGB-SPix having its color filter 34 only capable of giving way to red light, for example, in the wavelength range from 600 nm to 720 nm. Transparent block 36 is capable of giving way to infrared radiation and of giving way to visible light. Transparent block 36 may then correspond to a transparent resin block. As a variation, transparent block 36 is capable of giving way to infrared radiation and of blocking visible light. Transparent block 36 may then correspond to a black resin block or to an active layer, for example having a structure similar to that of active layer 26 and capable of only absorbing the radiation in the targeted spectrum.

Since filter 42 only gives way to the useful portion of near infrared, active layer 26 only receives the portion of the infrared radiation useful in the case where transparent block 36 is capable of giving way to infrared radiation and of blocking visible light. This advantageously enables to ease the design of active layer 26 having an absorption range which may be extensive and particularly comprise visible light. In the case where transparent block 36 is capable of giving way to infrared radiation and to visible light, the active layer 26 of infrared photodiode 2 will capture both infrared radiation and visible light. The determination of a signal only representative of the infrared radiation captured by infrared photodiode 2 may then be performed by linear combination of the signal delivered by the infrared photodiode 2 and the color photodiodes 4 of the pixel.

According to an embodiment, semiconductor substrate is made of silicon, preferably, of single crystal silicon. According to an embodiment, electronic components comprise transistors, particularly metal-oxide gate field-effect transistors, also called MOS transistors. Color photodiodes 4 are inorganic photodiodes, preferably made of silicon. Each color photodiode 4 comprises at least doped silicon region 14, which extends in substrate 10 from surface 12. According to an embodiment, substrate 10 is non-doped or lightly doped of a first conductivity type, for example, of type P and each region 14 is a doped region, of the conductivity type opposite to substrate 10, for example, type N. The depth of each region 14, measured from surface 12, may be in the range from 500 nm to 6 μm. Color photodiode 4 may correspond to a pinned photodiode. Examples of pinned photodiodes are particularly described in U.S. Pat. No. 6,677,656.

Conductive tracks 20, conductive vias 24, 30, and electrodes 22 may be made of a metallic material, for example, silver (Ag), aluminum (Al), gold (Au), copper (Cu), nickel (Ni), titanium (Ti), and chromium (Cr). Conductive tracks 20, conductive vias 24, 30, and electrodes 22 may have a monolayer or multilayer structure. Each insulating layer of stack 18 may be made of an inorganic material, for example, made of silicon oxide (SiO₂) or a silicon nitride (SiN).

Each electrode 28 is at least partially transparent to the light radiation that it receives. Each electrode 28 may be made of a transparent conductive material, for example, of transparent conductive oxide or TCO, of carbon nanotubes, of graphene, of a conductive polymer, of a metal, or of a mixture or an alloy of at least two of these compounds. Each electrode 28 may have a monolayer or multilayer structure.

Examples of TCOs capable of forming each electrode 28 are indium tin oxide (ITO), aluminum zinc oxide (AZO), and gallium zinc oxide (GZO), titanium nitride (TiN), molybdenum oxide (MoO₃), and tungsten oxide (WO₃). An example of a conductive polymer capable of forming each electrode 28 is the polymer known as PEDOT:PSS, which is a mixture of poly(3,4)-ethylenedioxythiophene and of sodium poly(styrene sulfonate), and polyaniline, also called PAni. Examples of metals capable of forming each electrode 28 are silver, aluminum, gold, copper, nickel, titanium, and chromium. An example of a multilayer structure capable of forming each electrode 28 is a multilayer AZO and silver structure of AZO/Ag/AZO type.

The thickness of each electrode 28 may be in the range from 10 nm to 5 μm, for example, in the order of 30 nm. In the case where electrode 28 is metallic, the thickness of electrode 28 is smaller than or equal to 20 nm, preferably smaller than or equal to 10 nm.

Each insulating layer 27, 32, 40 may be made of a fluorinated polymer, particularly the fluorinated polymer commercialized under trade name Cytop by Bellex, of polyvinylpyrrolidone (PVP), of polymethyl methacrylate (PMMA), of polystyrene (PS), of parylene, of polyimide (PI), of acrylonitrile butadiene styrene (ABS), of poly(ethylene terephtalate) (PET), of poly(ethylene naphtalate) (PEN), of cyclo olefin polymer (COP), en polydimethylsiloxane (PDMS), of a photolithography resin, of epoxy resin, of acrylate resin, or of a mixture of at least two of these compounds. As a variation, each insulating layer 27, 32, 40 may be made of an inorganic dielectric material, particularly of silicon nitride, of silicon oxide, or of aluminum oxide (Al₂O₃). The aluminum oxide may be deposited by atomic layer deposition (ALD). The maximum thickness of each insulating layer 27, 32, 50 may be in the range from 50 nm to 2 μm, for example, in the order of 100 nm.

The active layer 26 of each infrared pixel IR-Pix may comprise small molecules, oligomers, or polymers. These may be organic or inorganic materials, particularly quantum dots. Active layer 26 may comprise an ambipolar semiconductor material, or a mixture of an N-type semiconductor material and of a P-type semiconductor material, for example in the form of stacked layers or of an intimate mixture at a nanometer scale to form a bulk heterojunction. The thickness of active layer 26 may be in the range from 50 nm to 2 μm, for example, in the order of 200 nm.

Example of P-type semiconductor polymers capable of forming active layer 26 are poly(3-hexylthiophene) (P3HT), poly[N-9′-heptadecanyl-2,7-carbazole-alt-5,5-(4,7-di-2-thienyl-2′,1′,3′-benzothiadiazole)] (PCDTBT), poly[(4,8-bis-(2-ethylhexyloxy)-benzo[1,2-b;4,5-b′] dithiophene)-2,6-diyl-alt-(4-(2-ethylhexanoyl)-thieno[3,4-b] thiophene))-2,6-diyl] (PBDTTT-C), poly[2-methoxy-5-(2-ethyl-hexyloxy)-1,4-phenylene-vinylene] (MEH-PPV), or poly[2,6-(4,4-bis-(2-ethylhexyl)-4H-cyclopenta [2,1-b;3,4-b′]dithiophene)-alt-4,7(2,1,3-benzothiadiazole)] (PCPDTBT).

Examples of N-type semiconductor materials capable of forming active layer 26 are fullerenes, particularly C60, [6,6]-phenyl-C₆₁-methyl butanoate ([60]PCBM), [6,6]-phenyl-C₇₁-methyl butanoate ([70]PCBM), perylene diimide, zinc oxide (ZnO), or nanocrystals enabling to form quantum dots.

The active layer 26 of each infrared pixel IR-Pix may be interposed between first and second interface layers, not shown. According to the photodiode polarization mode, the interface layers ease the collection, the injection, or the blocking of charges from the electrodes into active layer 26. The thickness of each interface layer is preferably in the range from 0.1 nm to 1 μm. The first interface layer enables to align the work function of the adjacent electrode with the electronic affinity of the acceptor material used in active layer 26. The first interface layer may be made of cesium carbonate (CSCO₃), of metal oxide, particularly of zinc oxide (ZnO), or of a mixture of at least two of these compounds. The first interface layer may comprise a self-assembled monomolecular layer or a polymer, for example, (polyethyleneimine, ethoxylated polyethyleneimine, poly[(9,9-bis(3′-(N,N-dimethylamino)propyl)-2,7-fluorene)-alt-2,7-(9,9-dioctylfluorene)]. The second interface layer enables to align the work function of the other electrode with the ionizing potential of the donor material used in active layer 26. The second interface layer may be made of copper oxide (CuO), of nickel oxide (NiO), of vanadium oxide (V₂O₅), of magnesium oxide (MgO), of tungsten oxide (WO₃), of molybdenum oxide (MoO₃), of PEDOT:PSS, or of a mixture of at least two of these compounds.

Microlenses 38 have a micrometer-range size. In the present embodiment, each color sub-pixel RGB-SPix and each infrared pixel IR-Pix comprises a microlens 38. As a variation, each microlens 38 may be replaced with another type of micrometer-range optical element, particularly a micrometer-range Fresnel lens, a micrometer-range index gradient lens, or a micrometer-range diffraction grating. Microlenses 38 are converging lenses each having a focal distance f in the range from 1 μm to 100 μm, preferably from 1 μm to 10 μm. According to an embodiment, all microlenses 38 are substantially identical.

Microlenses 38 may be made of silica, of PMMA, of a positive photosensitive resin, of PET, of PEN, of COP, of PDMS/silicone, or of epoxy resin. Microlenses 38 may be formed by flowing of resist blocks. Microlenses 38 may further be formed by molding on a layer of PET, PEN, COP, PDMS/silicone or epoxy resin.

According to an embodiment, layer 40 is a layer which follows the shape of microlenses 38. Layer 40 may be obtained from an optically clear adhesive (OCA), particularly a liquid optically clear adhesive (LOCA), or a material with a low refraction index, or an epoxy/acrylate glue, or a film of a gas or of a gaseous mixture, for example, air. Preferably, when layer 40 follows the shape of microlenses 38, layer 40 is made of a material having a low refraction index, lower than that of the material of microlenses 38. Layer 40 may be made of a filling material which is a non-adhesive transparent material. According to another embodiment, layer 40 corresponds to a film which is applied against microlens array 38, for example, an OCA film. In this case, the contact area between layer 40 and microlenses 38 may be decreased, for example, limited to the tops of the microlenses. Layer 40 may then be formed of a material having a higher refraction index than in the case where layer 40 follows the shape of microlenses 38. According to another embodiment, layer 40 corresponds to an OCA film which is applied against microlens array 38, the adhesive having properties which enable film 40 to completely or substantially completely follow the surface of the microlenses.

According to the considered materials, the method of forming at least certain layers of image sensor 1 may correspond to a so-called additive process, for example, by direct printing of the material forming the organic layers at the desired locations, particularly in sol-gel form, for example, by inkjet printing, photogravure, silk-screening, flexography, spray coating, or drop casting. According to the considered materials, the method of forming the layers of image sensor 1 may correspond to a so-called subtractive method, where the material forming the organic layers is deposited all over the structure and where the non-used portions are then removed, for example, by photolithography or laser ablation. Methods such as spin coating, spray coating, heliography, slot-die coating, blade coating, flexography, or silk-screening, may in particular be used. When the layers are metallic, the metal is for example deposited by evaporation or by cathode sputtering over the entire support and the metal layers are delimited by etching.

Advantageously, at least some of the layers of image sensor 1 may be formed by printing techniques. The materials of the previously-described layers may be deposited in liquid form, for example, in the form of conductive and semiconductor inks by means of inkjet printers. “Materials in liquid form” here also designates gel materials capable of being deposited by printing techniques. Anneal steps may be provided between the depositions of the different layers, but it is possible for the anneal temperatures not to exceed 150° C., and the deposition and the possible anneals may be carried out at the atmospheric pressure.

In the embodiment illustrated in FIGS. 1 and 2, for each pixel of color and infrared images, electrode 28 may extend over all the color sub-pixels RGB-SPix and over infrared pixel IR-Pix, and via 30 is provided in areas which do not correspond to sub-pixels, for example, at the pixel periphery. Further, electrode 28 may be common to all the pixels of a same row and/or to all the pixels of the image sensor. In this case, via 30 may be provided at the periphery of image sensor 1. According to a variation, electrode 28 may only extend on active layer 26 and via 30 may be provided at the level of infrared pixel IR-Pix.

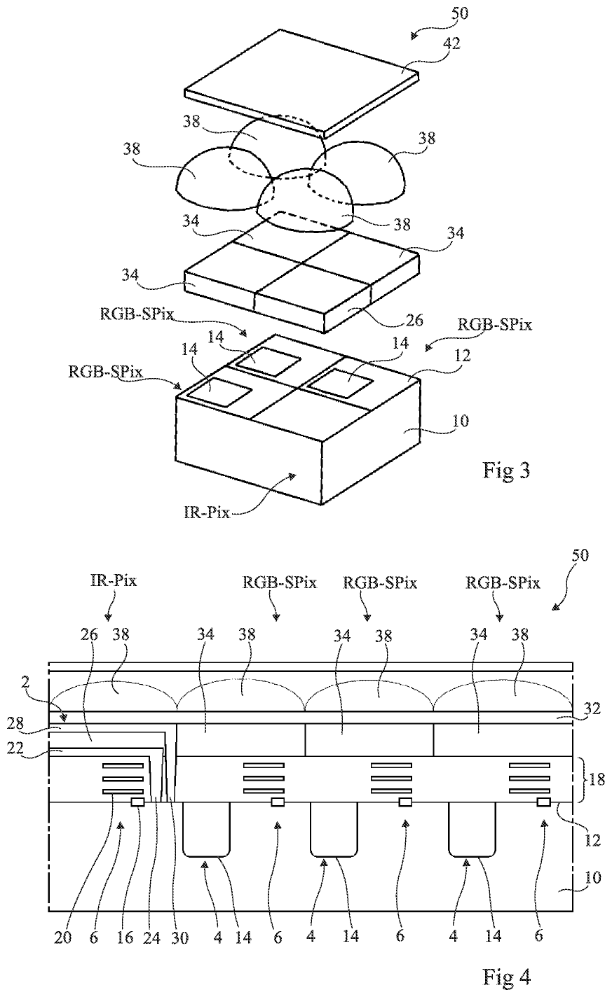

FIGS. 3 and 4 are drawings of another embodiment of an image sensor 50 respectively similar to FIGS. 1 and 2. Image sensor 50 comprises all the elements of the image sensor 1 shown in FIGS. 1 and 2, with the difference that insulating layer 32 is interposed between microlenses 38 and color filters 34, that active layer 26 is arranged at the location of block 36, which is not present, that is, at the same level as color filters 34, and that insulating layer 27 is not present. Further, electrode 28 only extends on active layer 26 and via 30 is provided at the level of infrared pixel IR-Pix. In this case, the active layer 26 of infrared photodiode 2 will capture both infrared radiation and visible light. The determination of a signal only representative of the infrared radiation captured by infrared photodiode 2 may then be performed by linear combination of the signal delivered by the infrared photodiode 2 and the color photodiodes 4 of the pixel.

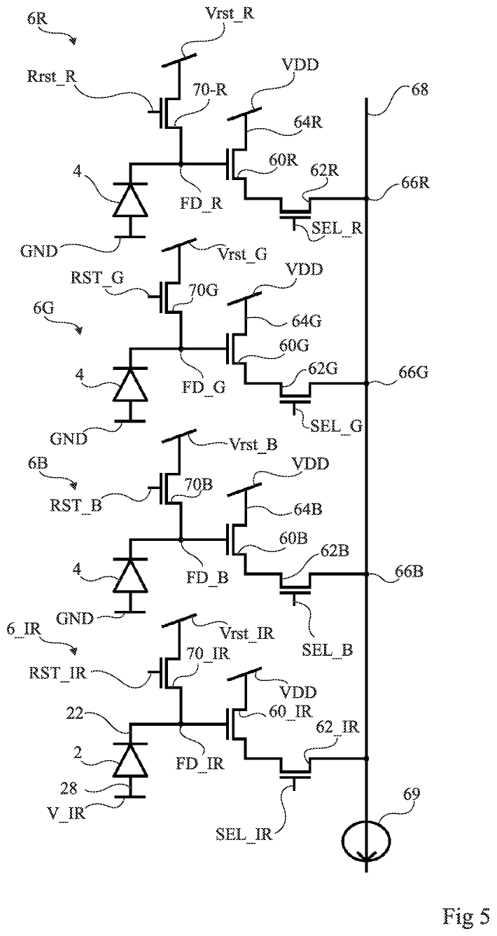

FIG. 5 shows the simplified electric diagram of an embodiment of readout circuits 6_R, 6_G, 6_B, associated with the color photodiode 4 of color sub-pixels RGB-SPix of pixels of the color image to be acquired and the readout circuit 6_IR associated with the infrared photodiode 2 of infrared pixel IR-Pix.

Readout circuits 6_R, 6_G, 6_B, and 6_IR have similar structures. In the following description, suffix “_R” is added to the reference designating a component of readout circuit 6_R, suffix “_G” is added to the reference designating the same component of readout circuit 6_G, suffix “_B” is added to the reference designating the same component of readout circuit 6_B, and suffix “_IR” is added to the reference designating the same component of readout circuit 6_IR.

Each readout circuit 6_R, 6_G, 6_B, 6_IR comprises a follower-assembled MOS transistor 60_R, 60_G, 60_B, 60_IR, in series with a MOS selection transistor 62_R, 62_G, 62_B, 62_IR between a first terminal 64_R, 64_G, 64_B, 64_IR and a second terminal 66_R, 66_G, 66_B, 66_IR. Terminal 64_R, 64_G, 64_B, 64_IR is coupled to a source of a high reference potential VDD in the case where the transistors forming the readout circuit are N-channel MOS transistors, or of a low reference potential, for example, the ground, in the case where the transistors forming the readout circuit are P-channel MOS transistors. Terminal 66_R, 66_G, 66_B, 66_IR is coupled to a conductive track 68. Conductive track 68 may be coupled to all the color sub-pixels and all the infrared pixels of a same column and be coupled to a current source 69 which does not form part of readout circuits 6_R, 6_G, 6_B, 6_IR. The gate of transistor 62_R, 62_G, 62_B, 62_IR is intended to receive a signal SEL_R, SEL_G, SEL_B, SEL_IR of selection of the color sub-pixel/infrared pixel. The gate of transistor 60_R, 60_G, 60_B, and 60_IR is coupled to a node FD_R, FD_G, FD_B, FR_IR. Node FD_R, FD_G, FD_B, FR_IR is coupled, by a reset MOS transistor 70_R, 70_G, 70_B, 70_IR, to a terminal of application of a reset potential Vrst_R, Vrst_G, Vrst_B, Vrst_IR, which potential may be VDD. The gate of transistor 70_R, 70_G, 70_B, 70_IR is intended to receive a signal RST_R, RST_G, RST_B, RST_IR for controlling the resetting of the color sub-pixel/infrared pixel, particularly enabling to reset node FD substantially to potential Vrst.

Node FD_R, FD_G, FD_B is coupled to the cathode electrode of the color photodiode 4 of the color sub-pixel. The anode electrode of color photodiode 4 is coupled to a source of a low reference potential GND, for example, the ground. Node FD_IR is coupled to the cathode electrode 22 of infrared photodiode 2. The anode electrode 28 of infrared photodiode 4 is coupled to a source of a reference potential V_IR. A capacitor, not shown, having an electrode coupled to node FD_R, FD_G, FD_B, FD_IR and having its other electrode coupled to the source of low reference potential GND, may be provided. As a variation, the role of this capacitor may be fulfilled by the stray capacitances present at node FD_R, FD_G, FD_B, FD_IR.

For each row of color sub-pixels associated with the same color, signals SEL_R, SEL_G, SEL_B, RST_R, RST_G, RST_B may be transmitted to all the color sub-pixels in the row. For each row of infrared pixels, signals SEL_IR, RST_IRB and potential V_IR may be transmitted to all the infrared pixels in the row. Signals Vrst_R, Vrst_G, Vrst_B, Vrst_IR may be identical or different. According to an embodiment, signals Vrst_R, Vrst_G, Vrst_B are identical and signal Vrst_IR is different from signals Vrst_R, Vrst_G, Vrst_B.

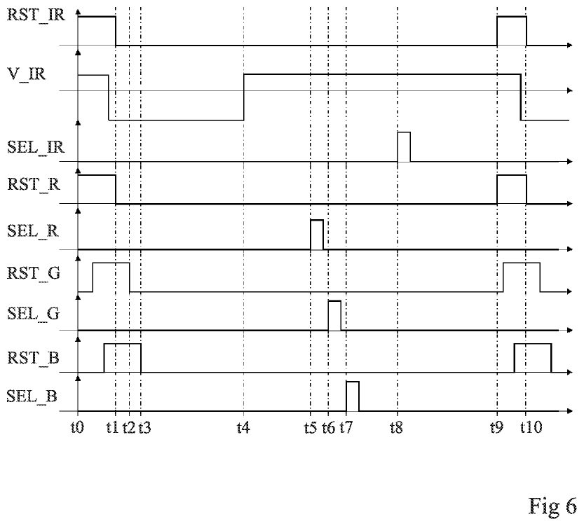

FIG. 6 is a timing diagram of binary signals RST_IR, SEL_IR, RST_R, SEL_R, RST_G, SEL_G, RST_B, SEL_B and of potential V_IR during an embodiment of an operating method of the readout circuits 6_R, 6_G, 6_B, 6_IR shown in FIG. 5. Call t0 to t10 successive times of an operating cycle. The timing diagram has been established considering that the MOS transistors of readout circuits 6_R, 6_G, 6_B, 6_IR are N-channel transistors.

At time t0, signals SEL_IR, SEL_R, SEL_G, and SEL_B are in the low state so that selection transistors 62_IR, 62_R, 62_G, and 62_B are blocked. The cycle comprises a phase of resetting the infrared pixel and the color sub-pixel associated with color red. For this purpose, signals RST_IR and RST_R are in the high state so that reset transistors 70_IR and 70_R are conductive. The charges accumulated in infrared photodiode 2 are then discharged to the source of Vrst_IR and the charges accumulated in the color photodiode 4 of the color sub-pixel associated with color red are then discharged to the source of potential Vrst_R.

Just before time t1, potential V_IR is set to a low level. At time t1, which marks the beginning of a new cycle, signal RST_IR is set to the low state so that transistor 70_IR is turned off and signal RST_R is set to the low state so that transistor 70_R is turned off. An integration phase then starts for the infrared photodiode 2, during which charges are generated and collected in photodiode 2 and for the photodiode 4 of the color sub-pixel associated with color red, during which charges are generated and collected in photodiode 4. At time t2, signal RST_G is set to the low state so that transistor 70_G is turned off. An integration phase then starts for the photodiode 4 of the color sub-pixel associated with color green, during which charges are generated and collected in photodiode 4. At time t3, signal RST_B is set to the low state so that transistor 70_B is turned off. An integration phase then starts for the photodiode 4 of the color sub-pixel associated with color blue, during which charges are generated and collected in photodiode 4.

At time t4, potential V_IR is set to a high level, which stops the charge collection in the infrared photodiode. The integration phase of infrared photodiode 2 thus stops.

At time t5, signal SEL_R is temporarily set to a high state, so that the potential of conductive track 68 reaches a value representative of the voltage at node FD_R and thus of the quantity of charges stored in the photodiode 4 of the color sub-pixel associated with color red. The integration phase of the photodiode 4 of the color sub-pixel associated with color red thus extends from time t1 to time t5. At time t6, signal SEL_G is temporarily set to a high state, so that the potential of conductive track 68 reaches a value representative of the voltage at node FD_G and thus of the quantity of charges stored in the photodiode 4 of the color sub-pixel associated with color green. The integration phase of the photodiode 4 associated with color green thus extends from time t2 to time t6. At time t7, signal SEL_B is temporarily set to a high state, so that the potential of conductive track 68 reaches a value representative of the voltage at node FD_B and thus of the quantity of charges stored in the photodiode 4 of the color sub-pixel associated with color blue. The integration phase of the photodiode 4 of the color sub-pixel associated with color blue thus extends from time t3 to time t7. At time t8, signal SEL_IR is temporarily set to a high state, so that the potential of conductive track 68 reaches a value representative of the voltage at node FD_IR and thus of the quantity of charges stored in infrared photodiode 2. At time t9, signals RST_IR and RST_R are set to the high state. Time t10 marks the end of the cycle and corresponds to the time t1 of the next cycle.

As shown in FIG. 6, the integration phases of the color photodiodes of the sub-pixels associated with a same pixel of the color image to be acquired are shifted in time. This enables to implement a rolling shutter type readout method for color photodiodes, where the integration phases of the pixel rows are shifted in time with respect to one another. Further, since the integration phase of infrared photodiode 2 is controlled by signal V-IR, the present embodiment advantageously enables to carry out a global shutter type readout method for the acquisition of the infrared image, where the integration phases of all the infrared photodiodes are simultaneously carried out.

In the case where the image sensor has the structure shown in FIGS. 3 and 4 or the structure shown in FIGS. 1 and 2 with block 36 which does not block visible light, infrared photodiode 4 may absorb near infrared radiation and also visible light. In this case, to determine the quantity of charges generated during an integration phase of the infrared photodiode only due to infrared radiation, one may be subtract from the signal delivered by infrared photodiode 2 the signals delivered by the color photodiodes 4 of the sub-pixels associated with the same image pixel. However, it is then preferable for the integration phases of the color sub-pixels to be simultaneous with the integration phase of infrared photodiode 2. Each readout circuit 6_R, 6_G, 6_B, 6_IR, shown in FIG. 5, may then further comprise a MOS transfer transistor between node FD_R, FR_G, FD_B, FD_IR and the cathode electrode of photodiode 4, 2. The transfer transistor enables to control the beginning and the end of the color photodiode integration phase so that a global shutter type readout method for the acquisition of the color image can be implemented.

Various embodiments and variants have been described. Those skilled in the art will understand that certain features of these embodiments can be combined and other variants will readily occur to those skilled in the art. In particular, the structure of the electrode 28 shown in FIG. 2, which covers photodiodes 4, may be implemented for the image sensor 50 shown in FIG. 4. Further, in the case where each readout circuit 6_R, 6_G, 6_B, 6_IR, shown in FIG. 5, further comprises a MOS transfer transistor between node FD_R, FR_G, FD_B, FD_IR and the cathode electrode of photodiode 4, 2, a readout method may be provided where a reading of a first value V1 representative of the potential of node FD_R, FD_G, FD_B, FD_IR may be carried out just after the turning on of reset transistor 70_R, 70_G, 70_B, 70_IR and a reading of a second value V2 representative of the potential of node FD_R, FD_G, FD_B, FD_IR may be carried out just after the turning on of the transfer transistor. The difference between values V2 and V1 is representative of the quantity of charges stored in the photodiode while suppressing the thermal noise due to reset transistor 70_R, 70_G, 70_B, 70_IR. Finally, the practical implementation of the embodiments and variants described herein is within the capabilities of those skilled in the art based on the functional description provided hereinabove.

1. A color and infrared image sensor comprising a silicon substrate, MOS transistors formed in the substrate and on the substrate, first photodiodes at least partly formed in the substrate, separate photosensitive blocks covering the substrate, and color filters covering the substrate, the image sensor further comprising first and second electrodes on either side of each photosensitive block and delimiting a second photodiode in each photosensitive block, the first photodiodes being configured to absorb the electromagnetic waves of the visible spectrum and each photosensitive block being configured to absorb the electromagnetic waves of the visible spectrum and of a first portion of the infrared spectrum, wherein the photosensitive blocks are made of organic materials.

2. The image sensor according to claim 1, further comprising an infrared filter, the color filters being interposed between the substrate and the infrared filter, the infrared filter being configured to give way to the electromagnetic waves of the visible spectrum, to give way to the electromagnetic waves of said first portion of the infrared spectrum, and to block the electromagnetic waves of at least a second portion of the infrared spectrum between the visible spectrum and the first portion of the infrared spectrum.

3. The image sensor according to claim 1, wherein the photosensitive blocks and the color filters are at the same distance from the substrate.

4. The image sensor according to claim 1, wherein the photosensitive blocks are closer to the substrate than the color filters.

5. The image sensor according to claim 4, wherein each photosensitive block is covered with a visible light filter made of organic materials.

6. The image sensor according to claim 1, further comprising an array of lenses interposed between the substrate and the infrared filter.

7. The image sensor according to claim 1, further comprising, for each pixel of the color image to be acquired, at least first, second, and third sub-pixels, each comprising one of the first photodiodes and one of the color filters, the color filters of the first, second, and third sub-pixels giving way to electromagnetic waves in different frequency ranges of the visible spectrum, and a fourth sub-pixel comprising one of the second photodiodes.

8. The image sensor according to claim 7, further comprising, for each first, second, and third sub-pixel, a first readout circuit coupled to the first photodiode and, for the fourth sub-pixel, a second readout circuit coupled to the second photodiode.

9. The image sensor according to claim 8, wherein, for each pixel of the color image to be acquired, the first readout circuits are configured to transfer first electric charges generated in the first photodiodes to a first electrically-conductive track and the second readout circuit is configured to transfer second charges generated in the second photodiode to the first electrically-conductive track or a second electrically-conductive track.

10. The image sensor according to claim 9, wherein the first photodiodes are arranged in rows and in columns, and wherein the first readout circuits are configured to control the generation of the first charges during first time intervals simultaneous for all the first photodiodes of the image sensor, or shifted in time from one row of first photodiodes to the other, or, for each pixel of the color image to be acquired, shifted in time for the first, second, and third sub-pixels.

11. The image sensor according to claim 9, wherein the second photodiodes are arranged in rows and in columns and wherein the second readout circuits are configured to control the generation of the second charges during second time intervals simultaneous for all the second photodiodes of the image sensor.
